(19) United States
(12) Patent Application Publication
(10) Pub. No.: US 2022/0044948 A1
(43) Pub. Date: Feb. 10, 2022

(54) MONITORING WAFER AND MONITORING SYSTEM

(71) Applicant: CHANGXIN MEMORY TECHNOLOGIES, INC., Hefei City, (CN)

(72) Inventors: Bowei ZHANG, Hefei City, (CN); Lei PAN, Hefei City (CN); Rong FU, Hefei City (CN)

(21) Appl. No.: 17/474,331

(22) Filed: Sep. 14, 2021

Related U.S. Application Data
(63) Continuation of application No. PCT/CN2021/100165, filed on Jun. 15, 2021.

(30) Foreign Application Priority Data
Aug. 5, 2020 (CN) 202010778734.8

(51) Int. Cl. H01L 21/67; H01L 21/66

(52) U.S. Cl. CPC H01L 21/67265; H01L 22/12

(57) ABSTRACT

The present disclosure provides a monitoring wafer and a monitoring system. The monitoring wafer includes: an initial wafer, a searchlight module, a data acquisition module and a wireless transmission module, the searchlight module is configured to emit searchlight to the wafer chuck, the data acquisition module is configured to acquire searchlight information of the searchlight on the wafer chuck, and the wireless transmission module is configured to receive and transmit the searchlight information.

### CROSS-REFERENCE TO RELATED APPLICATIONS

This is a continuation of International Application No. PCT/CN2021/100165, filed on Jun. 15, 2021, and entitled “MONITORING WAFER AND MONITORING SYSTEM”, which claims priority to Chinese patent application No. 202010778734.8, filed on Aug. 5, 2020, and entitled “MONITORING WAFER AND MONITORING SYSTEM”. The contents of International Application No. PCT/CN2021/100165 and Chinese patent application No. 202010778734.8 are hereby incorporated by reference in their entireties.

### TECHNICAL FIELD

The present disclosure relates to, but is not limited to, a monitoring wafer and a monitoring system.

### BACKGROUND

In the monolithic reaction process of a semiconductor structure, a plurality of wafers pass through the same reaction chamber in sequence to undergo corresponding fabricating processes. When the fabricating process of any wafer pollutes the environment in the reaction chamber or affects the performance of the reaction chamber, the fabricating processes of subsequent wafers or the quality of the semiconductor structure fabricated will be affected.

### SUMMARY

The following is the summary of subject matters detailed in the present disclosure. The summary is not intended to limit the protection scope of the claims.

Embodiments of the present disclosure provide a monitoring wafer, comprising: an initial wafer, the initial wafer having a front side and a back side, the back side facing a wafer chuck; and a wireless transmission module, as well as a searchlight module and a data acquisition module that are located on the back side, the searchlight module is configured to emit searchlight to the wafer chuck, the data acquisition module is configured to acquire searchlight information of the searchlight on the wafer chuck, and the wireless transmission module is configured to receive and transmit the searchlight information.

Embodiments of the present disclosure further provide a monitoring system, comprising: the monitoring wafer described in any one of the above; and a data analysis device, configured to receive searchlight information transmitted by the monitoring wafer.

### BRIEF DESCRIPTION OF THE DRAWINGS

The accompanying drawings incorporated into the description and constituting a part of the description illustrate the embodiments of the present disclosure, and are configured together with the description to explain the principles of the embodiments of the present disclosure. In these drawings, similar reference numerals are configured to denote similar elements. The drawings in the following description are some embodiments of the present disclosure, but not all embodiments. For those of ordinary skill in the art, other drawings can be obtained based on these drawings without paying any creative effort.

FIG. 1 is a schematic structure diagram of a monitoring wafer according to embodiments of the present disclosure;

FIG. 2 is a schematic structure diagram of a searchlight module of the monitoring wafer shown in FIG. 1;

FIGS. 3 to 6 are schematic diagrams of the working principle of the monitoring wafer according to embodiments of the present disclosure; and

FIG. 7 is a block diagram of a monitoring system according to embodiments of the present disclosure.

### DETAILED DESCRIPTION

In order to make the objectives, technical solutions and advantages of the embodiments of the present disclosure clearer, the embodiments of the present disclosure will be described in detail below with reference to the accompanying drawings. However, a person of ordinary skill in the art can understand that, in each embodiment of the present disclosure, many technical details are proposed in order to enable a reader to better understand the present application. However, the technical solutions of the present application may also be implemented without these technical details and various variations and modifications based on the following embodiments.

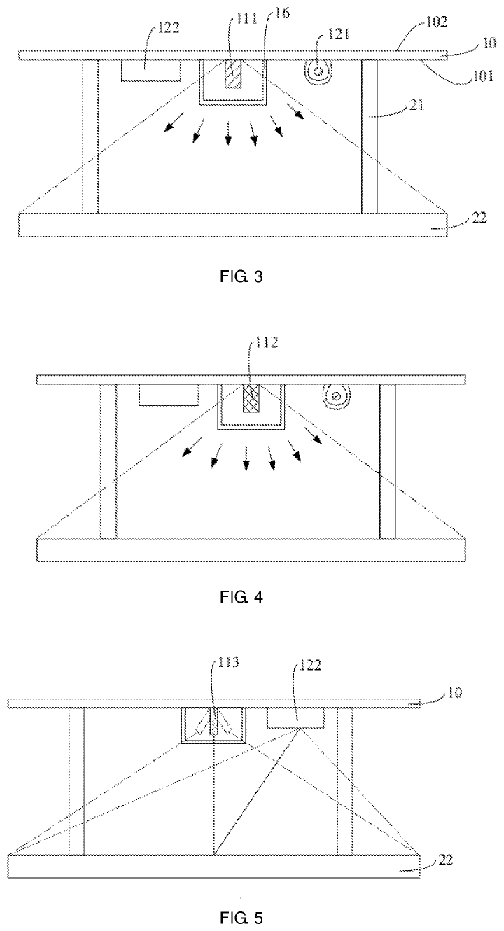

Referring to FIGS. 1 and 3, a monitoring wafer 1 comprises: an initial wafer 10, the initial wafer 10 having a front side 102 and a back side 101, the back side 101 facing a wafer chuck 22; and a wireless transmission module 13, as well as a searchlight module 11 and a data acquisition module 12 that are located on the back side 101, the searchlight module 11 is configured to emit searchlight to the wafer chuck 22, the data acquisition module 12 is configured to acquire searchlight information of the searchlight on the wafer chuck 22, and the wireless transmission module 13 is configured to receive and transmit the searchlight information.

The initial wafer 10 is a monitor wafer, and is configured to monitor the stability of a fabricating process between batches. The monitor wafer can be placed in an equipment or a reaction chamber together with a product wafer for the fabricating process, and can also undergo the fabricating process alone.

In this embodiment, the initial wafer 10 located in the reaction chamber for a monolithic reaction is taken as an example for description.

In order to ensure that the environment in the reaction chamber or the performance of the reaction chamber meet the requirements, the reaction chamber is often regularly opened for manual maintenance, but this may introduce other pollution and result in relatively low maintenance efficiency.

In this embodiment, the wafer chuck 22 can be an electrostatic chuck, and the wafer is fixed by means of static electricity. It should be noted that, when the wafer is fixed by the electrostatic chuck, the electrostatic chuck easily adsorbs organic impurities such as fibers. The wireless transmission module 13 can be located on the back side 101, and can also be located on a side or the front side 102 of the initial wafer 10.

In this embodiment, the searchlight module 11 can comprise a plurality of searchlight units. The plurality of searchlight units can be respectively a first searchlight unit 111, a second searchlight unit 112 and a third searchlight unit 113, and each of the searchlight units emits different searchlight. The monitoring wafer 1 further comprises a control module 14, and the control module 14 is configured to switch the plurality of searchlight units to emit different searchlight to the wafer chuck 22. As such, the statuses of the wafer chuck 22 and the reaction chamber under different searchlight environments can be obtained. Since different materials have different contrasts under different searchlight environments, the wafer chuck 22 is searched by using different searchlight, which is beneficial to detecting different types of contamination particles, and then maintaining the wafer chuck 22 and the reaction chamber more effectively.

The searchlight unit can emit searchlight at the beginning of the switching, can also emit searchlight after the switching, and can also emit searchlight all the time. Herein, the control module 14 switches the searchlight unit, the designated searchlight unit arrives at a designated position, and the searchlight unit emits searchlight at the same time.

In this embodiment, when the wireless transmission module 13 receives the searchlight information of different searchlight, the control module 14 is further configured to control the wireless transmission module 13 to transmit the searchlight information of the different searchlight to different target objects.

The target object can be a data analysis device for a certain type of searchlight. Configuring a corresponding data analysis device to analyze the searchlight information of a certain type of searchlight is beneficial to improving the analysis efficiency of the searchlight information of this type of searchlight, then obtaining the statues of the wafer chuck 22 and the reaction chamber more accurately and timely, and ensuring that the wafer chuck 22 and the reaction chamber are in good statuses; in addition, the target objects can also be different staffs who have different levels of cognition on different searchlight information, and the different staffs identify more familiar searchlight information, so that the searchlight information can be analyzed more accurately; moreover, the target objects can also be different functional devices such as a cleaning device and a movement device, the cleaning device can determine based on the searchlight information of a certain type of searchlight whether the reaction chamber and the wafer chuck 22 located in the reaction chamber need to be cleaned, and the movement device can determine based on the searchlight information of another type of searchlight whether the wafer chuck 22 needs to be moved and a corresponding movement amount.

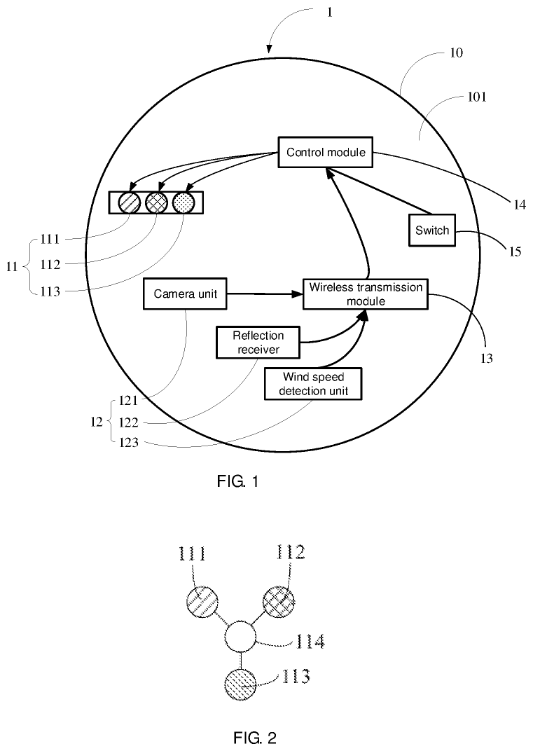

In this embodiment, referring to FIGS. 1, 2 and 3, the plurality of searchlight units can be fixed on a bearing structure 114, and the bearing structure 114 is rotatable, so that the surface of the wafer chuck 22 is located with searchlight ranges of the different searchlight units.

In this embodiment, the searchlight information comprises surface image information on the surface of the wafer chuck 22, and the data acquisition module 12 comprises a camera unit 121, the camera unit 121 is configured to obtain the surface image information. The surface image information can be configured to characterize the surface status of the wafer chuck 22. The surface image information can comprise structure topography and material distribution.

In this embodiment, the first searchlight unit 111 is a green light source, and the searchlight emitted by the first searchlight unit 111 is green light. Because the human eye is more sensitive to green light, it is easier for the human eye to recognize flaws and spots in a green light environment. Meanwhile, because the green light can improve the contrast of different materials on the surface of an object being tested, especially the contrast between metal and other materials, the green light is beneficial to manual detection of metal.

It should be noted that, the green light greatly improves the contrast of the surface image information of the wafer chuck 22; in addition, the metal material on the surface of the wafer chuck 22 may originate from other product wafers, or may originate from precursors that are not removed in the fabricating process.

In this embodiment, the second searchlight unit 112 is a purple light source, and the searchlight emitted by the second searchlight unit 112 is purple light. Through the contrast effect produced by purple light irradiation, the human eye can more easily observe tiny fluorescent materials, such as fibrous materials that are difficult to be removed due to electrostatic adsorption, so the purple light is beneficial to improving manual detection efficiency and detection accuracy.

It should be noted that the purple light greatly improves the contrast of spatial image information between the initial wafer 10 and the wafer chuck 22. During purple light search, the spatial image information between the initial wafer 10 and the wafer chuck 22 can be obtained using the camera unit 121. The spatial image information can be configured to characterize the contamination of the reaction chamber. Obtaining the spatial image information is beneficial to detecting impurity particles that are not deposited or adsorbed on the surface of the wafer chuck 22, so as to accurately obtain the contamination of the reaction chamber.

In this embodiment, the third searchlight unit 113 is a laser source, the light emitted by the third searchlight unit 113 is laser, and the third searchlight unit 113 can perform linear scanning in at least three directions; and the data acquisition module 12 further comprises a reflection receiver 122, the reflection receiver 122 is configured to receive reflected light of the searchlight and obtain energy data of the reflected light.

Since the laser has stronger energy, the use of laser for search can ensure that the reflected light of the searchlight has relatively high energy, and the reflected light is then received and recognized by the reflection receiver 122. In addition, when the laser scans to an edge position of the wafer chuck 22, due to the change of the dielectric material, the energy reflected by the wafer chuck 22 changes relatively obviously. As such, it can be determined according to the received energy data of the reflected light that the current position of the laser on the wafer chuck 22 is an edge point of the wafer chuck 22.

By obtaining three edge points, a center position of the wafer chuck 22 can be calculated. As such, the center of the wafer chuck 22 can be positioned, and the deviated wafer chuck 22 can be corrected, thereby avoiding etching defects caused by wafer position deviation and ensuring that the semiconductor structure has good performance.

The change of the reflected energy due to the change of the dielectric material comprises, but is not limited to, the following two situations: there is no other material on the edge of the wafer chuck 22, and when the laser irradiates on the edge of the wafer chuck 22, some light is not reflected by the wafer chuck 22, resulting in less energy of the reflected light received by the reflection receiver 122; and the edge of the wafer chuck 22 has other material with relatively low or high reflectivity, and when the laser irradiates on the edge point of the wafer chuck 22, because the reflectivity of some light decreases or increases, the energy of the reflected light received by the reflection receiver 122 also changes.

In addition, it can be determined according to the received energy data of the reflected light that the current position of the laser on the wafer chuck 22 is an edge point of the wafer chuck 22, for example, the control module 14 or an external data analysis device can obtain an optical path of searchlight according to the irradiation time of the third searchlight unit 113, or from the time of switching to the third searchlight unit 113 to the time when the reflection receiver 122 receives reflected light from an edge point, and obtain a position of the edge point according to the optical path and the scanning direction of the laser. In this embodiment, it can be considered that the distance from the third searchlight unit 113 to the edge point of the wafer chuck 22 is half of the optical path, and the optical path can be obtained by multiplying the round-trip time of the laser by the speed of light.

In this embodiment, the wireless transmission module 13 is further configured to receive a control command and send the control command to the control module 14, and the control module 14 is further configured to execute the control command, content of the control command comprises switching to a designated searchlight unit. The wireless transmission module 13 and the control module 14 have a receiving function, which is beneficial for a staff or other functional device to control the monitoring wafer 1 in real time, so as to achieve more targeted monitoring.

In this embodiment, the data acquisition module 12 further comprises a wind speed detection unit 123 configured to detect wind speed data, and the control module 14 is further configured to switch the searchlight unit according to the wind speed data.

The control module 14 is further configured to switch the searchlight unit according to the wind speed data, for example, the wireless transmission module 13 sends the wind speed data detected by the wind speed detection unit 123 to an external data analysis device, the data analysis device analyzes the wind speed data and sends a control command to the wireless transmission module 13 according to the analysis result, the wireless transmission module 13 sends the control command to the control module 14 for execution, and the control module 14 switches to the designated search unit according to the control command.

In this embodiment, the change in wind speed can occur in the following two but not limited to the following two situations: first, an inert air flow with a certain amount of heat is blown to the back side 101 of the initial wafer 10 to heat the wafer 10, and impurity particles in the reaction chamber may block a blowing port, thereby causing a fast flow rate at the blowing port or turbulence in the reaction chamber; second, in order to avoid damage to the wafer by the electrostatic adsorption force of the wafer chuck 22, a force opposite to the electrostatic adsorption force can be applied to the back side 101 by blowing air, so that the wafer has a certain distance from the wafer chuck 22 while being fixed, and at this time, the impurity particles in the reaction chamber may also block the blowing port, thereby causing a fast flow rate or turbulence.

In this embodiment, the monitoring wafer 1 further comprises a switch 15, the switch 15 is connected to the control module 14. The switch 15 can be turned on before the monitoring wafer 1 enters the reaction chamber to activate the control module 14. The switch 15 can also be turned off by the control module 14 after the monitoring wafer 1 leaves the reaction chamber, and the control module 14 is also turned off accordingly.

The following describes the monitoring wafer through exemplary practical application scenarios of the monitoring wafer.

In an application scenario, because the semiconductor structure fabricated in the reaction chamber has impurity defects, a monitoring wafer needs to be put into the reaction chamber to monitor the statuses of the wafer chuck and the reaction chamber, and to determine whether the wafer chuck has any impurity problem.

Referring to FIGS. 1 and 3, when the monitoring wafer 1 is transported onto the wafer chuck 22 by a front opening unified pod (FOUP), ejector pin 21 ejects the initial wafer 10 away from the wafer chuck 22 by a distance.

In this embodiment, the first searchlight unit 111 is first used for green light search, and the camera unit 121 transmits green light search information, mainly surface image information of the wafer chuck 22, to the external data analysis device special for green light through the wireless transmission module 13. In the case that the surface of the wafer chuck 22 does not have any impurity problem upon analysis, the data analysis device sends a control command executed by the control module 14 to the wireless transmission module 13, content of the control command is about switching the searchlight module 11 to the second searchlight unit 112 for purple light search.

The instruction “the first searchlight unit 111 is used for first search” can be either a built-in initial instruction of the control module 14, or a control by the data analysis device or the staff. In other embodiments, the second searchlight unit can also be used for first search.

In this embodiment, the searchlight module 11 is surrounded by a plane mirror 16, and the plane mirror 16 is configured to diffuse the light emitted by the searchlight module 11.

Referring to FIG. 4, the purple light search by the second searchlight unit 112 is performed after the green light search.

During the purple light search, the camera unit 121 transmits purple light search information, mainly spatial image information between the wafer chuck 22 and the initial wafer 10, to an external cleaning device through the wireless transmission module 13, the cleaning device having a data analysis function. In the case where there is an impurity problem in the reaction chamber upon analysis, a cleaning process is performed on the reaction chamber to remove impurities.

Before the cleaning process, the monitoring wafer can be controlled to move out of the reaction chamber, thereby avoiding the influence of the cleaning process on the performance of the monitoring wafer, and ensuring that the monitoring wafer has relatively high reusability. In other embodiments, the monitoring wafer and the reaction chamber are cleaned at the same time, which is beneficial to shortening the process time, does not need to put the monitoring wafer in again to monitor the contamination after cleaning, and is also beneficial to preventing impurity particles from being adsorbed on the surface of the monitoring wafer and from contaminating other process environments or other components with the removal of the monitoring wafer.

In other embodiments, when any impurity problem has not been analyzed out, the process is performed on the front side of the monitoring wafer to monitor process stability between batches.

In another application scenario, because the fabricated semiconductor structure has etching defects such as uneven etching or offsetting of the etching position, a monitoring wafer needs to be put into the reaction chamber to monitor the position of the wafer chuck, and to determine whether the wafer chuck is deviated.

It should be noted that the deviation of the wafer chuck will cause the position deviation of a product wafer, which in turn causes etching defects of the fabricated semiconductor structure, such as uneven etching. In order to ensure effective monitoring of the monitoring wafer, the position of the monitoring wafer itself needs to be accurate, that is, in the direction perpendicular to the surface of the wafer chuck, the orthographic projection of the center of the monitoring wafer should overlap the orthographic projection of the center of the wafer chuck before the deviation occurs.

In this embodiment, the wafer chuck can be closed while the monitoring wafer is put in, so as to avoid deviation of the monitoring wafer due to the electrostatic adsorption of the wafer chuck; or the monitoring wafer can be plated with an additional coating to avoid deviation of the monitoring wafer due to the electrostatic adsorption.

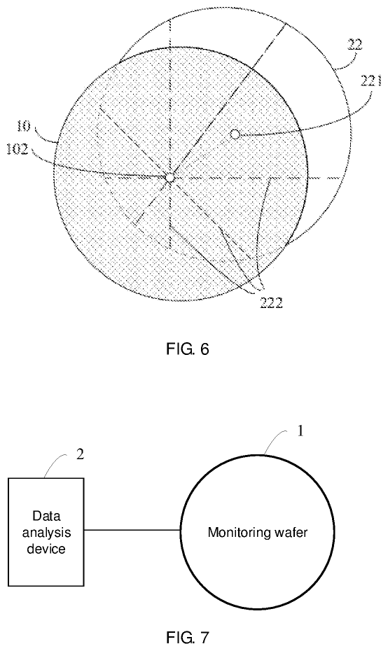

Referring to FIGS. 5 and 6, the third searchlight unit 113 scans the wafer chuck 22 in at least three directions, so as to obtain the positions of edge points of the wafer chuck 22.

In this embodiment, the third searchlight unit 113 is located at a first center position 102 on the back side of the initial wafer 10. FIG. 6 shows a scanning path 222. The scanning path 222 is a dotted line that exits from the first center position 102 to the edge of the wafer chuck 22. The third searchlight unit 113 performs linear scanning according to the scanning path 222.

The third searchlight unit 113 sends the scanning data to an external movement device through the wireless transmission module 13 (refer to FIG. 1) after the scanning is completed. The scanning data comprises energy data of the reflected light and time when the reflected light is received. The control module 14 (refer to FIG. 1) sends the scanning path 222 of the reflected light and the time when the third searchlight unit 113 emits laser corresponding to the scanning path 222 to the external movement device.

An analysis unit is arranged in the movement device, and the analysis unit analyzes the received data to obtain a duration of laser irradiation to the edge points and an optical path of the laser within the duration, and then obtains a position of each edge point according to the direction of the scanning path. The analysis unit can analyze a plane offset of a second center position 221 of the wafer chuck 22 relative to the first center position 102 according to the positions of at least three edge points, wherein the plane offset is a vector.

The movement device corrects the position of the wafer chuck 22 according to the plane offset to ensure that the wafer chuck 22 is in a preset position. As such, manual calibration is not required, which is beneficial to improving calibration efficiency and calibration accuracy, and avoiding new pollution introduced by the manual calibration, such as fibers on anti-static gloves.

In this embodiment, the monitoring wafer as a monitor wafer has a data acquisition module on the back side facing the wafer chuck, and data acquired by the data acquisition module can be transmitted out by the wireless transmission module, so as to accurately obtain the statuses of the wafer chuck and the reaction chamber without opening the reaction chamber or interrupting the fabricating process; in addition, the data acquisition module is located on the back side of the monitoring wafer, and the data monitored each time is acquired by a new monitoring wafer that enters the reaction chamber, thereby avoiding the influence of the fabricating process in the reaction chamber on the acquisition of the data acquisition module, and then ensuring the accuracy of data information acquired; moreover, as the functional modules such as the data acquisition module are located on the back side of the monitoring wafer, the monitoring wafer can also be configured to monitor process stability of the reaction chamber while monitoring the contamination of the wafer chuck and the reaction chamber.

Correspondingly, an embodiment of the present disclosure further provides a monitoring system. Referring to FIGS. 1, 2, 3 and 7, the monitoring system comprises: any of the above-mentioned monitoring wafers 1; and a data analysis device 2, the data analysis device 2 is configured to receive searchlight information transmitted by the monitoring wafer 1.

In this embodiment, the searchlight module 11 comprises a plurality of searchlight units, and searchlight emitted by each of the searchlight units is different; the monitoring wafer 1 comprises a control module 14, the control module 14 is configured to switch the searchlight units so as to emit different searchlight to the wafer chuck 22; and the data analysis device 2 is further configured to send a control command executed by the control module 14 to the monitoring wafer 1, content of the control command comprises switching to a designated searchlight unit.

In this embodiment, the data acquisition module 12 comprises a wind speed detection unit 123 configured to detect wind speed data at its location or a designated location, the wireless transmission module 13 is configured to receive the wind speed data and transmit the wind speed data to the data analysis device 2, and the data analysis device 2 is further configured to send the control command based on the wind speed data.

In this embodiment, through the data analysis device 2 and the monitoring wafer 1, the searchlight information of the wafer chuck 22 can be accurately obtained and analyzed without opening the reaction chamber or interrupting the fabricating process, so that a staff or other equipment carries out an operation related to the analysis result.

The control module 14 can be a microcontroller, an application specific logic circuit system (e.g., a field programmable gate array (FPGA), an application specific integrated circuit (ASIC), etc.), or other suitable processor. The suitable processor can be one or more general-purpose processors, such as microprocessors, central processing units, etc., and can also be one or more special-purpose processors, such as digital signal processors (DSP), network processors, etc.

The searchlight module 11 is configured to emit searchlight to the wafer chuck. The searchlight module 11 can includes a plurality of lighting fixtures and infrared imagers. The data acquisition module 12 is configured to acquire searchlight information of the searchlight on the wafer chuck. The data acquisition module 12 can includes cameras, optical receivers, and components for detecting wind speed. The wireless transmission module 13 is configured to receive and transmit the searchlight information. The wireless transmission module 13 can include circuit boards, transmission antennas, and transmission integrated circuits.

A person skilled in the art would readily conceive of other embodiments of the present disclosure after considering the disclosure of the description and practice. The present disclosure is intended to cover any variations, uses or adaptive changes of the present disclosure. These variations, uses or adaptive changes follow the general principle of the present disclosure and comprise common general knowledge or conventional technical means in the technical field that are not disclosed in the present disclosure. The description and the embodiments are merely regarded as exemplary, and the real scope and spirit of the present disclosure are pointed out by the following claims.

It should be understood that the present disclosure is not limited to the precise structure described above and shown in the drawings, and various modifications and changes can be made without departing from its scope. The scope of the present disclosure is only limited by the appended claims.

### INDUSTRIAL APPLICABILITY

According to the monitoring wafer and the monitoring method provided in the present disclosure, the monitoring wafer as a monitor wafer has a data acquisition module on the back side facing the wafer chuck, and data acquired by the data acquisition module can be transmitted out by the wireless transmission module, so as to accurately obtain the statuses of the wafer chuck and the reaction chamber without opening the reaction chamber or interrupting the fabricating process; in addition, the data acquisition module is located on the back side of the monitoring wafer, and the monitored data is acquired by a new monitoring wafer that enters the reaction chamber every time, thereby avoiding the influence of the fabricating process in the reaction chamber on the acquisition of the data acquisition module of the monitoring wafer, and then ensuring the accuracy of data information acquired; moreover, as the functional modules such as the data acquisition module are located on the back side of the monitoring wafer, the monitoring wafer can also be configured to monitor process stability of the reaction chamber while monitoring the contamination of the wafer chuck and the reaction chamber.

1. A monitoring wafer, comprising:
an initial wafer, the initial wafer having a front side and a back side, the back side facing a wafer chuck; and
a wireless transmission module, as well as a searchlight module and a data acquisition module that are located on the back side, the searchlight module is configured to emit searchlight to the wafer chuck, the data acquisition module is configured to acquire searchlight information of the searchlight on the wafer chuck, and the wireless transmission module is configured to receive and transmit the searchlight information.

2. The monitoring wafer according to claim 1, wherein the searchlight information comprises surface image information on a surface of the wafer chuck; and the data acquisition module comprises a camera unit, the camera unit is configured to obtain the surface image information.

3. The monitoring wafer according to claim 2, wherein the searchlight comprises green light.

4. The monitoring wafer according to claim 2, wherein the searchlight comprises purple light.

5. The monitoring wafer according to claim 4, wherein the searchlight information further comprises spatial image information between the back side and the wafer chuck; and the camera unit is further configured to obtain the spatial image information.

6. The monitoring wafer according to claim 1, wherein the searchlight comprises laser, and the searchlight module can perform linear scanning in at least three directions; and the data acquisition module comprises a reflection receiver, the reflection receiver is configured to receive reflected light of the searchlight and obtain energy data of the reflected light.

7. The monitoring wafer according to claim 1, wherein the searchlight module comprises a plurality of searchlight units, and the searchlight emitted by each of the searchlight units is different; and the monitoring wafer further comprises a control module, the control module is configured to switch the searchlight units so as to emit different searchlight to the wafer chuck.

8. The monitoring wafer according to claim 7, wherein the control module is further configured to control the wireless transmission module to transmit the searchlight information of the different searchlight to different target objects.

9. The monitoring wafer according to claim 7, wherein the wireless transmission module is further configured to receive a control command and send the control command to the control module, and the control module is further configured to execute the control command, content of the control command comprises switching to a designated searchlight unit.

10. The monitoring wafer according to claim 7, wherein the data acquisition module further comprises a wind speed detection unit configured to detect wind speed data, and the control module is further configured to switch the searchlight unit according to the wind speed data.

11. A monitoring system, comprising:
at least one monitoring wafer according to claim 1; and
a data analysis device, configured to receive searchlight information transmitted by the monitoring wafer.

12. The monitoring system according to claim 11, wherein the searchlight module comprises a plurality of searchlight units, and searchlight emitted by each of the searchlight units is different; the monitoring wafer comprises a control module, the control module is configured to switch the searchlight units so as to emit different searchlight to a wafer chuck; and the data analysis device is further configured to send a control command executed by the control module to the monitoring wafer, content of the control command comprises switching to a designated searchlight unit.

13. The monitoring system according to claim 12, wherein a data acquisition module comprises a wind speed detection unit configured to detect wind speed data, and a wireless transmission module is configured to receive the wind speed data and transmit the wind speed data to the data analysis device; and the data analysis device is further configured to send the control command based on the wind speed data.
